(19) United States
(12) Patent Application Publication
(10) Pub. No.: US 2009/0320924 A1
(43) Pub. Date: Dec. 31, 2009

(54) Solar Cell Structure

(76) Inventors: Jen-inn CHYI, Jhongii City (TW); Cheng-yu Chen, Jhongii City (TW)

Correspondence Address: HDLS Patent & Trademark Services, P.O. BOX 220746, CHANTILLY, VA, 20153-0746, US

(21) Appl. No.: 12/187,716

(22) Filed: Aug. 7, 2008

(30) Foreign Application Priority Data
Jun. 30, 2008 (TW) 097124537

(51) Int. Cl. H01L 31/06; H01L 31/0264

(52) U.S. Cl. 136/262; 136/265; 257/E31.004

(57) ABSTRACT

A solar cell structure includes a substrate, a buffer layer on the substrate, a type II band alignment nanostructure layer on the buffer layer, a p-type area and an n-type area defined on the type II band alignment nanostructure layer, and a p-type metal electrode and an n-type metal electrode coated onto the p-type and n-type areas, respectively. The type II band alignment nanostructure layer is provided for distributing an electron current and a hole current in different channels to minimize the recombination of electrons and holes and improve the photoelectric conversion efficiency of the solar cell significantly.

### FIELD OF THE INVENTION

The present invention relates to a solar cell structure, and more particularly to a solar cell structure having an absorption layer of a type II band alignment structure, and the structure conducting currents horizontally to improve both optical current extraction efficiency and photoelectric conversion efficiency of the solar cell.

### BACKGROUND OF THE INVENTION

At present, the photoelectric conversion efficiency of mass produced crystalline silicon solar cells available in the market is only 17˜20%, indicating that most of the sunlight absorbed by the solar cells are released in the form of heat energy.

In general, present multifunction (or tandem) solar cell structures absorb photons of different wavelengths by different band gap materials to enhance the overall photoelectric conversion efficiency, and these structures are used in the solar cell with the highest efficiency. In the solar cell structure as shown in FIG. 6, germanium (Ge) 101, gallium arsenide (GaAs) 102 and indium gallium phosphide (InGaP) 103 are grown on a germanium substrate 100 to form a multifunction solar cell, and the photoelectric conversion efficiency of such solar cell is up to 40.7% under focusing sunlight, but the epitaxy structure is complicated and requires much longer growth time and higher cost.

In recent years, an intermediate band solar cell structure is developed, and an additional energy band is introduced between a conduction band and a valence band. Such structure generally adopts a p-i-n structure, while using high density and multi-stack quantum dots in the i-layer to form an intermediate band and absorb photons with different wavelengths according to different quantum dot materials. However, the efficiency is not up to our expectation and the production of the optical current is not significant. Furthermore, the intermediate band alignment reduces the open circuit voltage, and thus the efficiency of the solar cell cannot be improved significantly. Another group has developed a type II GaSb/GaAs quantum dot solar cell as shown in FIG. 7, wherein a GaAs buffer layer 201 is grown on a GaAs substrate 200, and then an n-type barrier layer 202 and a plurality of GaSb quantum dot layers 203 are grown, and finally a p-type barrier layer 204 is grown to complete the solar cell of the type II band alignment structure. The long life time of excitons is used for improving the optical current. However it also constitutes a confinement to the holes, and thus the optical current and the photoelectric conversion efficiency cannot be improved significantly.

### SUMMARY OF THE INVENTION

In view of the foregoing shortcomings of the prior art, the inventor of the present invention based on years of experience in the related industry to conduct extensive researches and experiments, and finally developed a solar cell structure in accordance with the present invention to overcome the shortcomings of the prior art.

Therefore, it is a primary objective of the present invention to provide a type II band alignment nanostructure layer, whose wave functions of the electrons and holes decrease the overlapped portion leading to reduce the probability of the recombination of carriers, so as to increase the life time of the excitons. After the p-type and n-type electrodes are installed appropriately, the electrons and holes can be transmitted quickly and transversally from an electron current to an n-type electrode, and from a hole current to a p-type electrode (refer to FIG. 1 for the schematic view of electrons and holes being transmitted in the type II band alignment nanostructure layer) to reduce the probability of the recombination of electrons and holes and overcome the drawback of a low photoelectric conversion efficiency.

### BRIEF DESCRIPTION OF THE DRAWINGS

FIG. 1 is a schematic view of conducting electrons and holes in a type II band alignment nanostructure layer in accordance with the present invention;

FIG. 2 is a schematic view of a preferred embodiment of the present invention;

FIG. 3 is a schematic view of a structure of a first quantum dot absorption area in accordance with the present invention;

FIG. 4 is a schematic view of another preferred embodiment of the present invention;

FIG. 5 is a schematic view of a structure of a second quantum dot absorption area in accordance with the present invention;

FIG. 6 is a schematic view of a structure of a conventional multifunction solar cell; and

FIG. 7 is a schematic view of a type II GaSb/GaAs quantum dot solar cell.

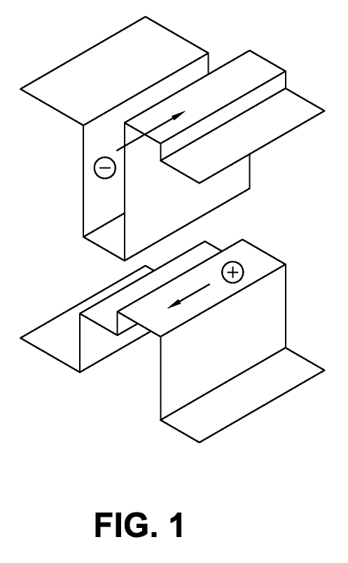

### DETAILED DESCRIPTION OF THE PREFERRED EMBODIMENTS

To make it easier for our examiner to understand the technical measures and the operating procedure of the invention, we use preferred embodiments together with the attached drawings for the detailed description of the invention.

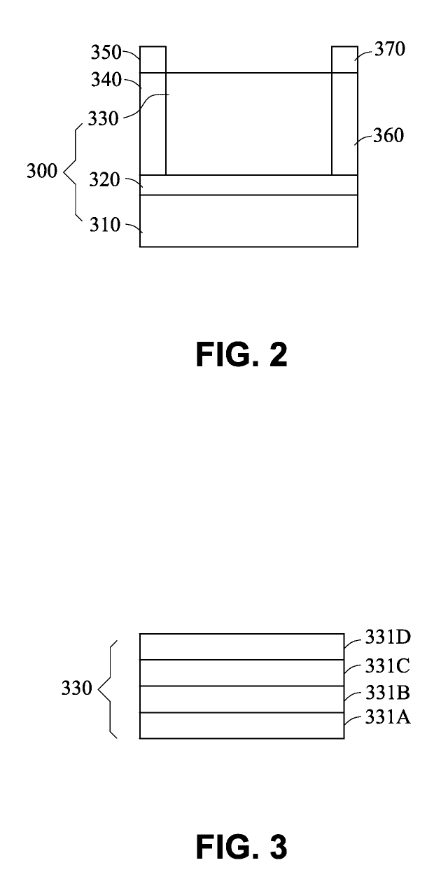

The present invention discloses a solar cell structure, and more particularly to a type II band alignment nanostructure layer for reducing the probability of the recombination of electrons and holes to improve the life time of carriers and enhance the photoelectric conversion efficiency of the solar cell. With reference to FIG. 2 for a preferred embodiment of the present invention, the growing method of the solar cell structure comprises the following steps:

Firstly, a first buffer layer 320 (which is an undoped GaAs buffer layer in this invention) is grown on a first substrate 310 (which is a semi-insulating GaAs substrate).

Secondly, a first quantum dot absorption area 330 (which is an absorption area of the type II band alignment nanostructure layer) is covered onto the first buffer layer 320, wherein the first substrate 310, the first buffer layer 320 and the first quantum dot absorption area 330 are combined into a quantum dot epitaxy structure 300.

Thirdly, an ion implantation method is used for implanting beryllium ions and silicon ions on a quantum dot epitaxy structure 300, while forming a p-type ion implantation area 340 and an n-type ion implantation area 360, and activating the beryllium ions and silicon ions by a thermal activation processing.

Finally, a p-type ohmic contact 350 made of platinum/titanium/platinum/gold (Pt/Ti/Pt/Au) and an n-type ohmic contact 370 made of titanium/gold (Ti/Au) are plated onto the p-type ion implantation area 340 and the n-type ion implantation area 360 respectively to complete the solar cell structure.

With reference to FIG. 3 for a method of growing the first quantum dot absorption area 330, the method comprises the following steps:

Firstly, a first quantum well layer 331B (which is a first InAs quantum dot layer in this invention is grown on a first barrier layer 331A (which is a first n-type GaAs barrier layer in this invention).

Secondly, a first cap layer 331C (which is a first GaAsSb cap layer in this invention, and the value x of GaAs1-xSbx falls within a range of 0.14 to 1) is grown on the first quantum dot layer 331B.

Thirdly, a first barrier layer 331D (which is a first p-type GaAs barrier layer in this invention) is grown on the first cap layer 331C, wherein the first barrier layer 331A, the first quantum dot layer 331B, the first cap layer 331C and the first barrier layer 331D are combined into a diode unit.

Finally, the diode unit grows periodically to form a stacked epitaxy structure to complete the first quantum dot absorption area 330.

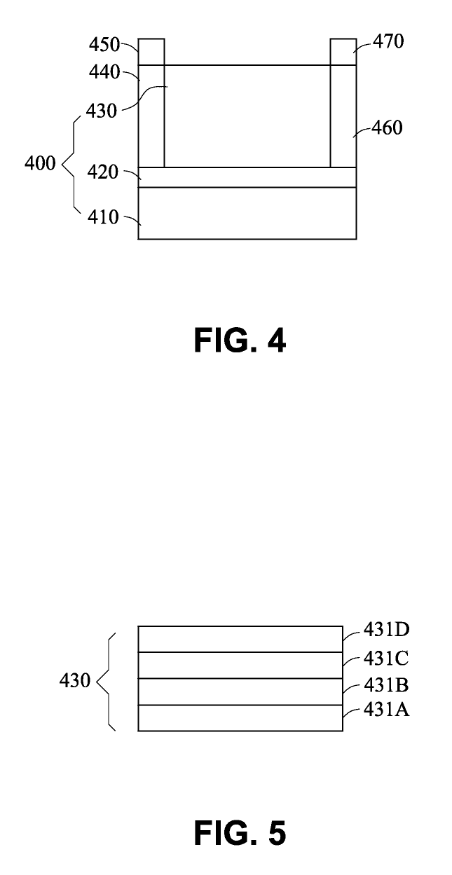

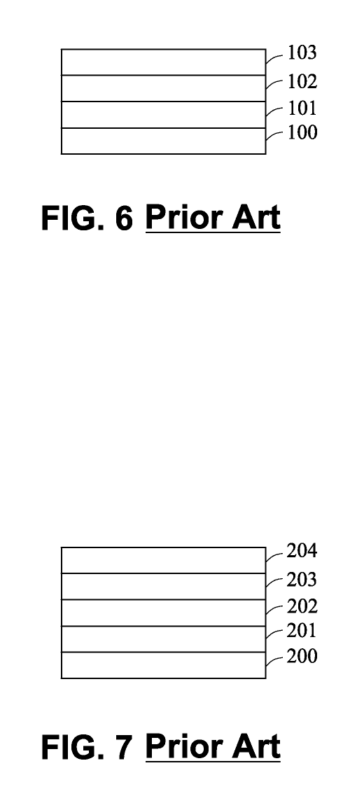

With reference to FIG. 4 for a solar cell structure in accordance with another preferred embodiment of the present invention, the growing method of the solar cell structure comprises the following steps:

Firstly, a second buffer layer 420 (which is an undoped GaAs buffer layer in this invention) is grown on a second substrate 410 (which is a semi-insulating GaAs substrate in this invention).

Secondly, a second quantum well absorption area 430 is covered onto the second buffer layer 420, wherein the second substrate 410, the second buffer layer 420 and the second quantum well absorption area 430 are combined into a type II quantum well epitaxy structure 400.

Thirdly, a thermal diffusion method is used for diffusing zinc ions and silicon ions on the type II quantum well epitaxy structure 400, while forming a perpendicular p-type ion diffusion area 440 and a perpendicular n-type ion diffusion area 460.

Finally, the p-type ion diffusion area 440 and the n-type ion diffusion area 460 are plated onto a p-type ohmic contact 450 made of platinum/titanium platinum//gold (Pt/Ti/Pt/Au) alloy and made of an n-type ohmic contact 470 made of titanium/gold (Ti/Au) to complete the solar cell structure.

With reference to FIG. 5 for a method of growing the second quantum well absorption area 430, the method comprises the following steps:

A second quantum well layer 431B is grown on the second barrier layer 431A, wherein the second quantum well layer 431B of the invention is a first p-type GaAs barrier layer.

A second cap layer 43 1C is grown on the second quantum well layer 43 1B, wherein the second cap layer 431C of the invention is a GaAsSb cap layer.

A second barrier layer 431D is grown on the second cap layer 431C, wherein the second barrier layer 431D of the invention is a GaAs barrier layer.

The second barrier layer 431A, the second quantum well layer 431B, the second cap layer 431C and the second barrier layer 431D are combined into another diode unit.

Finally, the diode unit goes through a periodical growth to form a stacked epitaxy structure, and complete the second quantum well absorption area 430.

In view of the description above, the difference of the method in accordance with the present invention and the prior art resides on that:

1. The invention adopts the type II quantum structure, whose electrons and holes increase the life time and the diffusion distance of carriers, while using a lateral conduction to reduce the electrons and holes from being absorbed by the epitaxy layer, so as to overcome the shortcomings of the conventional solar cell. Obviously, the invention is novel and improves over the prior art.

2. The invention enhances the photoelectric conversion efficiency of the solar cell significantly, and complies with the patent application requirements.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A solar cell structure, comprising:
a buffer layer, grown on a substrate;
an n-type semiconductor, grown on the buffer layer;
a type II band alignment nanostructure layer, grown on the n-type semiconductor;
a p-type semiconductor, grown on the nanostructure;
an n-type area and a p-type area, penetrated into each layer; and
a p-type metal electrode and an n-type metal electrode, coated onto the p-type area and the n-type area, respectively.

2. The solar cell structure of claim 1, wherein the substrate is made of a material selected from the collection of a semiconductor, an insulator, a conductor, a polymer and a compound.

3. The solar cell structure of claim 2, wherein the substrate is one selected from the collection of an n-type substrate, a p-type substrate and an undoped substrate.

4. The solar cell structure of claim 1, wherein the buffer layer is one selected from the collection of an n-type layer, a p-type layer and a undoped layer.

5. The solar cell structure of claim 1, wherein the type II band alignment nanostructure layer is one selected from the collection of a quantum well layer, a nanorod layer and a quantum dot layer.

6. The solar cell structure of claim 1, wherein the type II band alignment nanostructure layer comprises:
a first nanostructure layer, grown on a first barrier layer; and
a first cap layer, grown on the first nanostructure layer.

7. The solar cell structure of claim 6, wherein the first nanostructure layer is one selected from the collection of an n-type layer, a p-type layer and a undoped layer.

8. The solar cell structure of claim 6, wherein the first cap layer is one selected from an n-type layer, a p-type layer and a undoped layer.

9. The solar cell structure of claim 6, wherein the type II band alignment nanostructure layer is made of a material selected from the collection of GaAs/GaSb, InAs/GaAsSb, InAs/InGaAsSb, InAs/AlSb, InGaAs/GaAsSb, InGaAs/InGaAsSb, InGaAsSb/GaSb, InP/InAlAs, InP/AlGaAsSb, GaNAs/InGaN, ZnTe/CdSe and ZnS/ZnTe.

10. The solar cell structure of claim 1, wherein the type II band alignment nanostructure layer is comprised of a single layer or multi-layers.

11. The solar cell structure of claim 10, wherein if the type II band alignment nanostructure layer is comprised of a plurality of layers, each layer is grown with a same material or a different material.

12. The solar cell structure of claim 1, wherein the substrate is a structure with a perpendicular p-type area and a perpendicular n-type area.

13. The solar cell structure of claim 12, wherein the p-type area and the n-type area are penetrated into each layer by a method selected from the collection of an ion implantation, a thermal diffusion, an epitaxy method, a p-type metal formation and an n-type metal formation.
